(19) United States
(12) Patent Application Publication
(10) Pub. No.: US 2013/0078793 A1
(43) Pub. Date: Mar. 28, 2013

(54) METHOD FOR DEPOSITING A GATE OXIDE AND A GATE ELECTRODE SELECTIVELY

(71) Applicants: Qingqing Sun, Shanghai (CN); Ye Li, Shanghai (CN); Runchen Fang, Shanghai (CN); Pengfel Wang, Shanghai (CN); Wei Zhang, Shanghai (CN)

(72) Inventors: Qingqing Sun, Shanghai (CN); Ye Li, Shanghai (CN); Runchen Fang, Shanghai (CN); Pengfel Wang, Shanghai (CN); Wei Zhang, Shanghai (CN)

(21) Appl. No.: 13/528,446

(22) Filed: Jun. 20, 2012

(30) Foreign Application Priority Data
Sep. 23, 2011 (CN) CN 201110285019.1

(51) Int. Cl. H01L 21/28

(52) U.S. Cl. 438/591; 257/E21.19

(57) ABSTRACT

The present invention belongs to the technical field of integrated semiconductor circuits, and relates to a method for depositing a gate oxide and a gate electrode selectively. The present invention makes use of Octadecyltriethoxysilane's (ODTS') easy attachment to the Si—OH interface and difficult attachment to the Si—H interface, and selectively deposits the gate oxide and gate electrode materials, which avoids the unnecessary waste of materials and saves cost. Meanwhile, the present invention will transfer the etching of the gate oxide and gate electrode into the etching of SiO₂ so as to reduce the difficulty of the etching process and increase the production efficiency.

### CROSS-REFERENCE TO RELATED APPLICATION

This application is a continuation of and claims priority to Chinese Patent Application No. CN201110285019.1 filed on Sep. 23, 2011, the entire content of which is incorporated by reference herein.

### BACKGROUND OF THE INVENTION

1. Technical Field

The present invention belongs to the technical field of integrated semiconductor circuit, relates to a method for manufacturing a gate oxide and a gate electrode, and more specifically, to a method for depositing a gate oxide and a gate electrode selectively.

2. Description of Related Art

With the continuous reduction of the feature size of Metal-Oxide-Semiconductor Field Effect Transistors (MOSFET), the insulated gate dielectric layer is also becoming thinner and thinner according to the principle of reducing in equal proportion, and when the gate dielectric layer is thin enough, problems such as its reliability, especially the time-related breakdown and the impurities in gate electrodes diffusing into the substrate will seriously influence the stability and reliability of devices. Now, SiO₂ as the gate dielectric has reached its physical limit, and the quantum direct tunneling effect will lead to a remarkable increase of leakage current of the gate, which will increase the power consumption of devices and also do harm to the reliability. The replacement of SiO₂ gate dielectric with high-k gate dielectric can largely increase its physical thickness without changing the equivalent oxide thickness (EOT), which can reduce the leakage current of the gate.

The high-k gate dielectric material has become popular in replacing the SiO₂ because it has solved many problems caused by SiO₂'s closeness to the limit of physical thickness. However, the combination of polycrystalline silicon and high-k gate dielectric materials such as HfO₂ will cause a lot of problems such as the depletion effect of polycrystalline silicon's gate, Fermi level pinning, overly high gate resistance, and boron penetration. As a result, it is inevitable to replace the polycrystalline silicon gate electrodes with metal gates. In the traditional process, the forming process of gates is to first depositing a gate oxide and a gate electrode, and then photo lithography and etching of the gate oxide and gate electrode to obtain a gate, wherein the etching process is very difficult to perform and has a low yield.

Atomic layer deposition is a method realized by using the surface saturated reaction on the substrate treated through surface bioactive treatment, which is not sensitive to temperature and reactant flux. During the process of atomic layer deposition, the chemical reaction of a new atomic film is directly related to the former layer, which can deposit only one layer of atoms in each reaction. Compared with the traditional deposition process, atomic layer deposition can accurately control the thickness and chemical components of the film, and the film deposited will have good uniformity and conformity, which is considered the most promising technique in integrated circuit for manufacturing films. The selective deposition means the realization of the development of the films' deposition in some particular surfaces through chemical modification to different substrates of integrated circuits by using chemical reagents such as Octadecyltriethoxysilane (ODTS), which can reduce the waste of materials.

### BRIEF SUMMARY OF THE INVENTION

In view of this, the present invention aims at providing a method for manufacturing a gate through selective deposition technology to reduce the waste of materials and meanwhile, decrease the difficulty of etching gate oxide and gate electrode so as to increase the yield rate.

To achieve the above purpose of the present invention, a method for depositing a gate oxide and a gate electrode selectively is provided in the present invention, including the following steps:
provide a semiconductor substrate and rinse it;
isolate the field oxygen area;
grow a layer of silicon dioxide;
deposit a layer of photoresist;
define the position of the gate through photo lithography and etching;
remove the photoresist;
treat the surface of the silicon dioxide;
attach a layer of ODTS on the silicon dioxide;
deposit a high-k gate dielectric;
deposit a metal electrode;
remove the ODTS and silicon dioxide.

Further, the thickness of silicon dioxide is 50-200 nm. The high-k gate dielectric is selected from Pr₂O₃, TiO₂, HfO₂, Al₂O₃ or ZrO₂ with a thickness of 2-20 nm. The metal electrode is formed by metal gate materials such as TiN, TaN, Ru or W.

Furthermore, the surface treatment of silicon dioxide includes the following steps: first, treat the surface with piranha solution at room temperature (the volume ratio of H₂SO₄ with a concentration of 95-98% and H₂O₂ is 7:3); secondly, immerse it for 1-3 minutes in the HF acid solution with a concentration of 2%; and lastly, rinse it off with deionized water.

The method for depositing a gate oxide and a gate electrode selectively provided by the present invention has the following advantages:

1. Deposit the gate oxide and gate electrode materials selectively by using the feature of ODTS's easy attachment to the Si—OH interface and difficult attachment to the Si—H interface, which avoids unnecessary waste of materials and also saves cost.

2. Transfer the etching of the gate oxide and gate electrode into the etching of SiO₂, which reduces the difficulty of the etching process and improves the production efficiency.

3. Develop the major parts of the high-k gate dielectric and metal gate through atomic layer deposition, which ensures the quality of the high-k gate dielectric layer as well as its good contact with the metal gate.

### BRIEF DESCRIPTION OF THE SEVERAL VIEWS OF THE DRAWINGS

FIG. 1 is a process flow diagram of the method for depositing a gate oxide and a gate electrode selectively provided by the present invention.

FIG. 2-FIG. 8 are the process flow diagrams of an embodiment of manufacturing a gate through the method of depositing a gate oxide and a gate electrode selectively provided by the present invention.

### DETAILED DESCRIPTION OF THE INVENTION

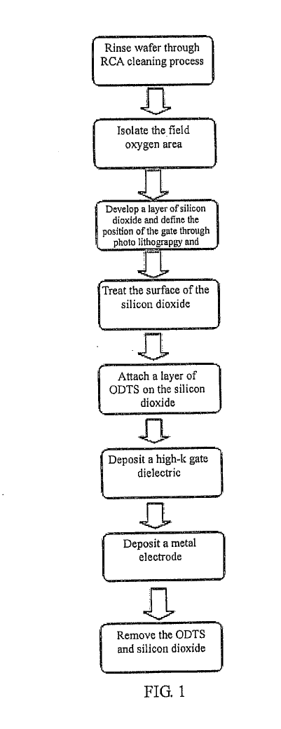

FIG. 1 is a process flow diagram of the method for depositing a gate oxide and a gate electrode selectively provided by the present invention. The method includes the following steps: provide a semiconductor substrate and rinse it through the RCA cleaning process; isolate the field oxide area; develop a layer of silicon dioxide; define the position of the gate through photo lithography and etching; treat the surface of the silicon dioxide; attach a layer of ODTS on the silicon dioxide; deposit a high-k gate dielectric; deposit a metal electrode; remove the ODTS and silicon dioxide.

The present invention is further detailed in combination with the drawings and the embodiments below. In the drawings, the thicknesses of layers and regions are either zoomed in or out for the convenience of description, so it shall not be considered as the true size. Although the drawings cannot accurately reflect the true size of the devices, they still reflect the relative position among regions and composition structures, especially the up-down and the adjacent relations. The drawings are schematic and shall not be considered as a limit to the scope of the present invention. Meanwhile, the term “Substrate” used in the following description can be considered as a semiconductor substrate during the manufacturing process, and other film layers prepared on it may also be included.

The method for depositing a gate oxide and a gate electrode selectively provided by the present invention applies to the preparation of gates of different MOS devices, and the following description is an embodiment of manufacturing the gates of NMOSFET devices through the method provided by the present invention.

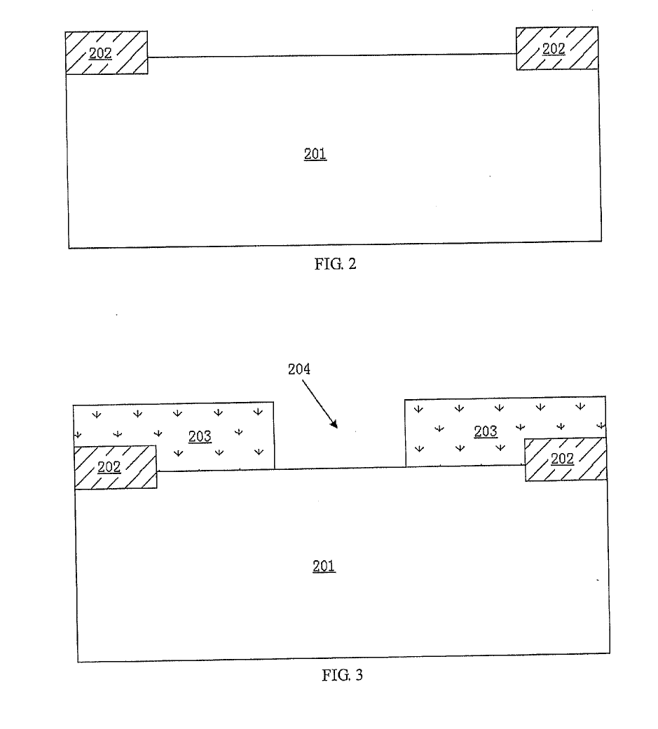

First, provide a p-type Si substrate 201 and rinse the Si substrate through traditional RCA cleaning process, immerse it for 1-3 minutes in the HF acid solution with a concentration of 2% to remove the oxide layer on the surface, and then blow-dry the Si substrate with N₂. Then, isolate the field oxygen area through the method of LOCOS, and the specific process as below: develop an oxide layer of the buffer layer, deposit Si₃N₄ through the LPCVD process, and then form the field oxygen area 202 through photo lithography and etching, as shown in FIG. 2.

Next, develop a layer of silicon dioxide 203 with a thickness of 100 nm, deposit a layer of photoresist, define the position 204 of the gate though photo lithography and etching, and the structure after the removal of photresist is as shown in FIG. 3.

Next, treat the silicon dioxide 203 with piranha solution (the volume ratio of H2SO₄ with a concentration of 95-98% and H₂O₂ is 7:3) for 20 minutes at room temperature, then immerse it for 2 minutes in the HF acid solution with a concentration of 2%, and last rinse it with deionized water, thus obtaining the result that the Si—OH interface is formed on the surface of silicon dioxide 203 and the Si—OH interface on the surface of Si substrate 201, as shown in FIG. 4.

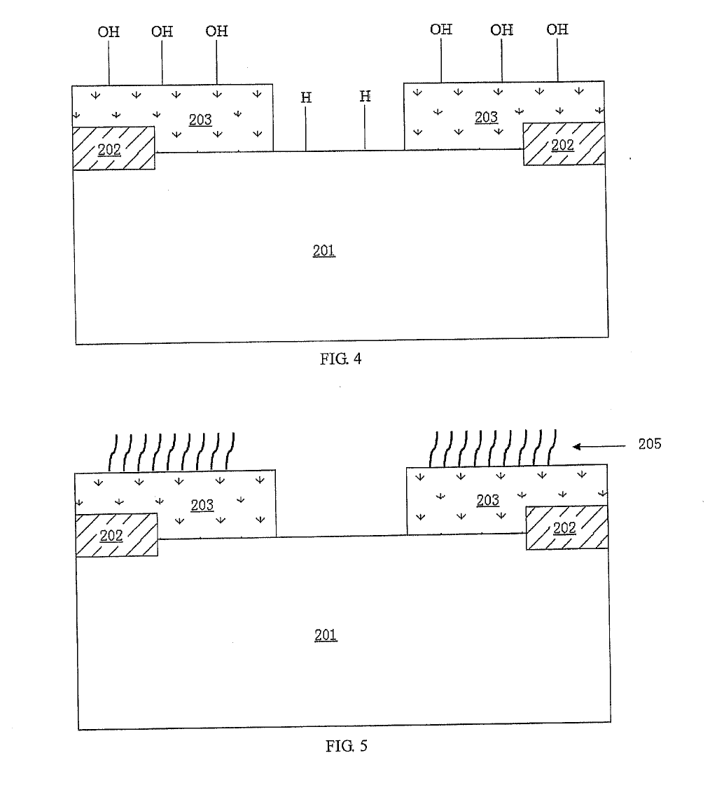

Next, immerse the base plate in the ODTS solution for 48 hours, then rinse it with toluene, acetone and chloroform, and blow-dry it with N₂. Thus, by taking advantage of the feature of ODTS's easy attachment to the Si—OH interface and difficult attachment to the Si—H interface, a layer 206 of ODTS can be formed on the surface of the silicon dioxide 203, as shown in FIG. 5.

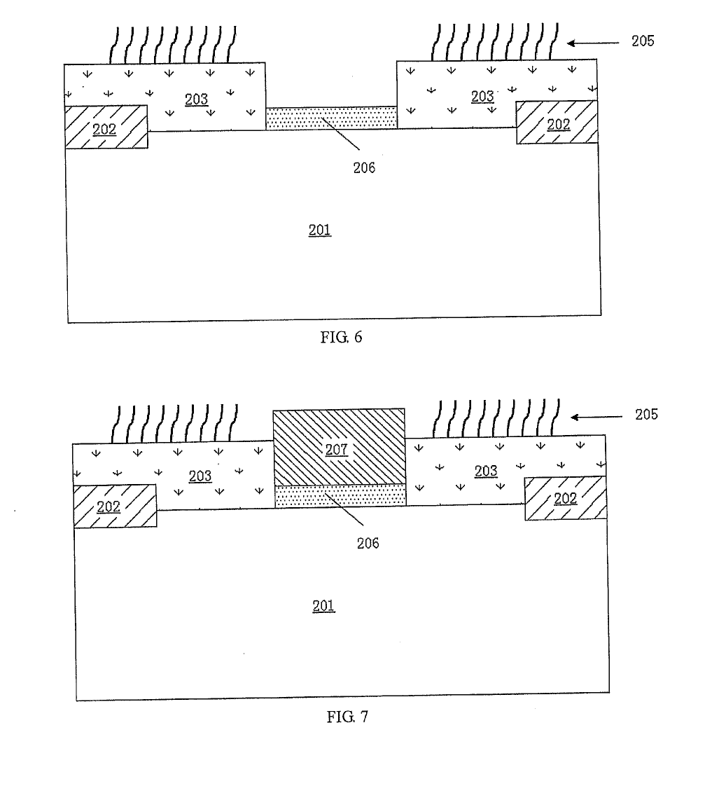

Next, develop a high-k gate dielectric layer 206 through atomic layer deposition (ALD), as shown in FIG. 6. The high-k gate dielectrics such as Al₂O₃ and HfO₂ have a reaction temperature of 200° C. and 300° C. and a velocity of 0.1 nm/cycle and 0.09 nm/cycle respectively.

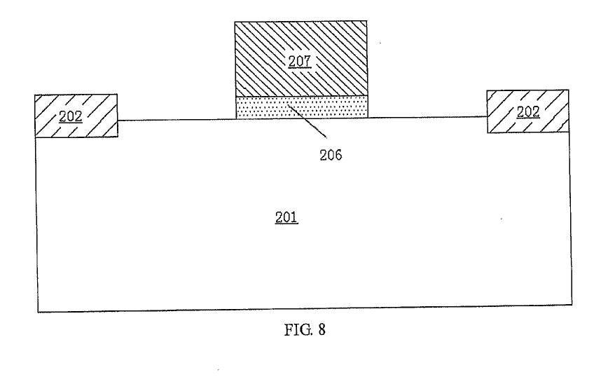

Afterwards, deposit a gate electrode 207, as shown in FIG. 7, taking W, TiN, Ru, TaN as materials, the specific process is as follows: first of all, deposit the nucleating layer of the gate electrode through atomic layer deposition, and then deposit the major parts through chemical vapor deposition (CVD).

At last, remove the ODTS 205 and silicon dioxide 203, as shown in FIG. 8.

As described above, without deviating from the spirit and scope of the present invention, there may be many significantly different embodiments. It shall be understood that the present invention is not limited to the specific embodiments described in the Specification except those limited by the Claims herein.

What is claimed is:

1. A method for depositing a gate oxide and a gate electrode selectively, characterized in that it is comprised of the following steps:
provide a semiconductor substrate and rinse it;
isolate the field oxygen area;
develop a layer of silicon dioxide;
define the position of the gate through photo lithography and etching;
treat the surface of the silicon dioxide;
attach a layer of Octadecyltriethoxysilane (ODTS) on the silicon dioxide;
deposit a high-k gate dielectric;
deposit a metal electrode;
remove the ODTS and silicon dioxide.

2. The method for depositing a gate oxide and a gate electrode selectively according to claim 1, characterized in that the thickness of silicon is 50-200 nm.

3. The method for depositing a gate oxide and a gate electrode selectively according to claim 1, characterized in that the process of the surface treatment to the silicon dioxide is as below: firstly, treat the surface with piranha solution for 15-25 minutes at room temperature, then immerse it in the HF acid solution with a concentration of 2%, and in the end, rinse it off with deionized water.

4. The method for depositing a gate oxide and a gate electrode selectively according to claim 1, characterized in that the high-k gate dielectric material is selected from Pr₂O₃, TiO₂, HfO₂, Al₂O₃ or ZrO₂ with the thickness of 2-20 nm.

5. The method for depositing a gate oxide and a gate electrode selectively according to claim 1, characterized in that the metal electrode is formed by metal gate materials such as TiN, TaN, Ru or W.
